(19) United States
(12) Patent Application Publication
(10) Pub. No.: US 2015/0270416 A1
(43) Pub. Date: Sep. 24, 2015

(54) SOLAR CELL

(71) Applicant: Panasonic Intellectual Property Management Co., Ltd., Osaka (JP)

(72) Inventors: Kazunori FUJITA, Gifu (JP); Yasuko HIRAYAMA, Osaka (JP); Hirotada INOUE, Hyogo (JP)

(21) Appl. No.: 14/733,135

(22) Filed: Jun. 8, 2015

Related U.S. Application Data
(63) Continuation of application No. PCT/JP2013/006793, filed on Nov. 19, 2013.

(30) Foreign Application Priority Data
Dec. 13, 2012 (JP) 2012-272063

(51) Int. Cl. H01L 31/0236; H01L 31/0376

(52) U.S. Cl. CPC H01L 31/02366; H01L 31/0376

(57) ABSTRACT

Provided is a solar cell comprising a photoelectric conversion unit on which textures are formed, and an electrode that includes a plurality of conductive particles. The average size of the textures is adjusted so that the diameter of an inscribed circle in a space surrounded by the ridgelines of a plurality of textures that are adjacent to each other in the textures and a virtual line that connects the vertices of the adjacent textures is smaller than the average particle size of the conductive particles.

### CROSS REFERENCE TO RELATED APPLICATIONS

This application is a continuation under 35 U.S.C. §120 of PCT/JP2013/006793, filed Nov. 19, 2013, which is incorporated herein reference and which claimed priority under 35 U.S.C. §119 to Japanese Application No. 2012-272063, filed Dec. 13, 2012, the entire content of which is also incorporated herein by reference.

### TECHNICAL FIELD

The present invention relates to a solar cell.

### BACKGROUND ART

A technique is known to provide textures having depressions and projections of several μm to several tens of μm on a light receiving surface of a solar cell in order to increase power generation efficiency in the solar cell. By providing the textures, it is possible to reduce the reflection of light entering the light receiving surface from the outside, and increase the efficiency of confining light in the solar cell (see Patent Literatures 1 and 2).

Regarding the solar cell, a technique has been used that applies a conductive paste onto the textures by, for example, screen printing to form a collector electrode (see Patent Literature 3).

### CITATION LIST

### Patent Literature

### Patent Literature 1: Japanese Unexamined Patent Application Publication No. 2010-93194

### Patent Literature 2: Japanese Unexamined Patent Application Publication No. 2011-515872

### Patent Literature 3: Japanese Patent Publication No. 3271990

### SUMMARY OF INVENTION

### Technical Problem

When the conductive paste is printed on a substrate on which the textures are formed or printed on a thin film formed on the substrate in the manufacturing process of the solar cell, the conductive paste may seep along the gap between a screen plate and the textures. The seepage of the conductive paste beyond a range necessary as the collector electrode may cause a light blocking loss in the solar cell.

### Solution to Problem

According to the present invention, a solar cell includes a photoelectric conversion unit which has a first surface and a second surface opposite to the first surface and in which textures are formed on at least the first surface, and an electrode which is formed on the first surface and which includes a plurality of conductive particles. The average size of the textures is formed so that the diameter of an inscribed circle in a space surrounded by the ridgelines of a plurality of textures that are adjacent to each other among the above textures and a virtual line that connects the vertices of the adjacent textures is smaller than the average particle size of the conductive particles.

### Advantageous Effects of Invention

According to a solar cell of the present invention, it is possible to accurately form an electrode into a desired shape by screen printing of a conductive paste.

### BRIEF DESCRIPTION OF DRAWINGS

FIG. 1 is a plan view showing the structure of a solar cell according to an embodiment of the present invention;

FIG. 2 is a sectional view showing the structure of the solar cell according to the embodiment of the present invention;

FIG. 3 is a view showing the structure of textures according to the embodiment of the present invention;

FIG. 4 is a view showing a formation method of a collector electrode according to the embodiment of the present invention;

FIG. 5 is a drawing substitutive photograph of a microscopic observation showing the aspect of the textures according to the embodiment of the present invention;

FIG. 6 is a plan view illustrating the relation between the texture and the shape of a conductive filler according to the embodiment of the present invention;

FIG. 7 is a side view illustrating the relation between the textures and the shape of the conductive filler according to the embodiment of the present invention;

FIG. 8 is a view illustrating the relation between the textures and the diameter of the conductive filler according to the embodiment of the present invention; and

FIG. 9 is a graph showing the relation between the size of the textures and the diameter of an inscribed circle according to the embodiment of the present invention.

### DESCRIPTION OF EMBODIMENT

An embodiment of the present invention will be described below in detail, but the present invention is not limited thereto. The drawings referred to in the embodiment are schematically shown, and the dimensions and ratios of components shown in the drawings may be different from actual dimensions and ratios. Specific dimensions and ratios should be judged in consideration of the following explanation.

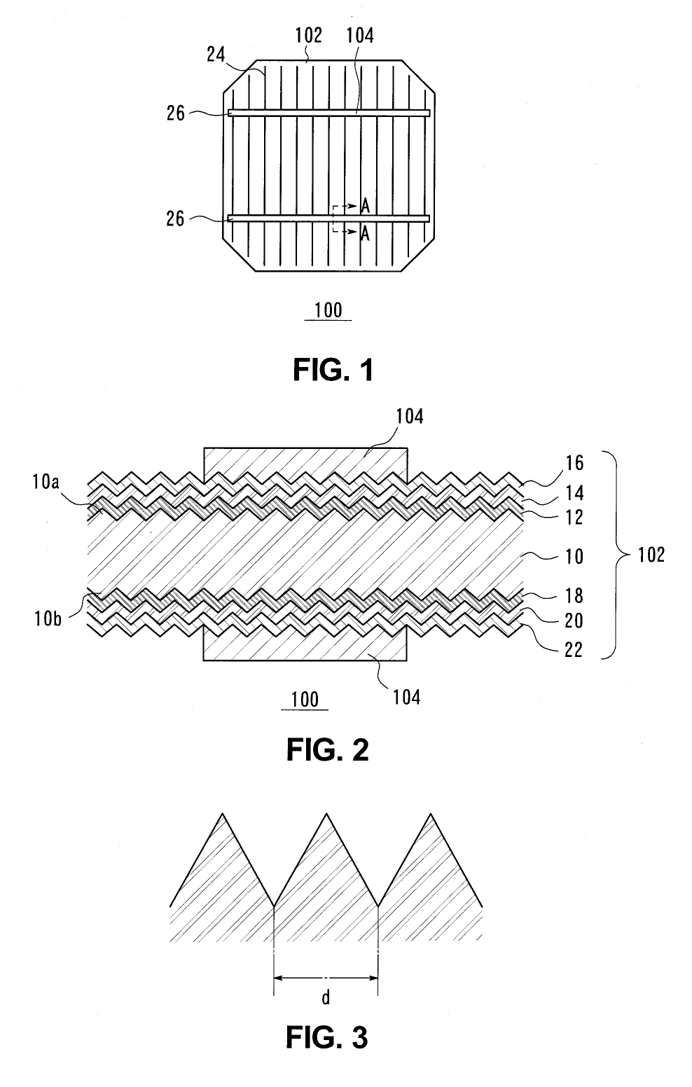

As shown in FIG. 1 and FIG. 2, a solar cell 100 according to the present embodiment includes a photoelectric conversion unit 102 and collector electrodes 104.

FIG. 2 is a sectional view taken along the line A-A in FIG. 1. A “light receiving surface” represents a main surface which light mainly enters from the outside of the photoelectric conversion unit 102, and a “rear surface” represents a main surface opposite to the light receiving surface. For example, from over 50% to 100% of solar light entering the photoelectric conversion unit 102 enters from the side of the light receiving surface.

The photoelectric conversion unit 102 has a semiconductor junction such as a pn junction and a pin junction, and is made of a crystalline semiconductor material such as monocrystalline silicon or polycrystalline silicon.

For example, the photoelectric conversion unit 102 can be configured by stacking an i-type amorphous silicon layer 12, a p-type amorphous silicon layer 14, and a transparent conductive layer 16 on the side of the light receiving surface of a substrate 10 made of n-type crystalline silicon and stacking an i-type amorphous silicon layer 18, an n-type amorphous silicon layer 20, and a conductive layer 22 on the rear side. The solar cell having such a configuration is called a hetero junction type solar cell, and is considerably increased in conversion efficiency by the insertion of an intrinsic (i-type) amorphous silicon layer in the pn junction formed by crystalline silicon and the p-type amorphous silicon layer. The conductive layer 22 on the rear side may be transparent or may be nontransparent. The photoelectric conversion unit 102 is not limited to silicon, and may be a semiconductor material.

It is preferable that textures 10a and 10b are formed on both surfaces of the substrate 10 before the layers are stacked. The textures 10a and 10b have a surface depressed and projected structure which suppresses surface reflection to increase the light absorption amount of the photoelectric conversion unit 102.

The textures 10a and 10b can be formed by anisotropic etching of a (100) face of the substrate 10 using an alkaline solution such as a sodium hydroxide (NaOH) solution, a potassium hydroxide (KOH) solution, or a tetramethylammonium hydroxide (TMAH). If the substrate 10 having the (100) face is immersed in the alkaline solution, the substrate 10 is anisotropically etched along a (111) face, and a large number of square-pyramid-shaped projections are formed on the surface of the substrate 10. For example, the concentration of the alkaline solution contained in an etching solution is preferably 1.0 weight percent to 7.5 weight percent.

It is also preferable to use a solution in which an alcoholic substance is mixed with the above alkaline solutions. The alcoholic substance includes, for example, isopropyl alcohol (IPA), cyclohexanediol, and octanol. By using such a mixed solution, it is possible to inhibit the readhesion of fragments or reaction products generated in the anisotropic etching to the substrate 10. It is preferable that the alcoholic substance is contained at 1 weight percent to 10 weight percent.

Another way of forming textures on a monocrystalline or polycrystalline substrate may be to disperse metallic particles of, for example, silver on the substrate 10 and etch the substrate 10 with a mixed solution of hydrofluoric acid and a hydrogen peroxide solution.

The size of the textures 10a and 10b can be adjusted by conditions such as the composition ratio and concentration of the solution used for etching, the time required for etching, and the temperature during etching. Here, the size of the textures 10a and 10b is represented by a distance d between adjacent valleys of the textures 10a and 10b as shown in FIG. 3. In a plane observation photograph of the surface of the substrate 10 obtained using a scanning electron microscope (SEM), an area of the approximation of the textures that are quadrate is measured, and the square root of the average value of the areas of several hundred textures is the average size of the textures 10a and 10b.

The i-type amorphous silicon layer 12, the p-type amorphous silicon layer 14, the i-type amorphous silicon layer 18, and the n-type amorphous silicon layer 20 can be formed by, for example, plasma enhanced chemical vapor deposition (PECVD), catalytic chemical vapor deposition (Cat-CVD), or a sputtering method. As the PECVD, any of the following methods may be used; for example, an RF plasma CVD method, a high-frequency VHF plasma CVD method, or a microwave plasma CVD method.

A source gas in which, for example, silane (SiH₄) is diluted with hydrogen (H₂) is used to form the i-type amorphous silicon layers 12 and 18 by CVD. In the case of the p-type amorphous silicon layer 14, it is possible to use a source gas in which diborane (B₂H₆) is added to silane and which is diluted with hydrogen (H₂). In the case of the n-type amorphous silicon layer 20, it is possible to use a source gas in which phosphine (PH₃) is added to silane and which is diluted with hydrogen (H₂).

For example, the i-type amorphous silicon layer 12 having a thickness of about 5 nm is formed on the side of the light receiving surface of the substrate 10, and the p-type amorphous silicon layer 14 having a thickness of about 5 nm is further formed. The i-type amorphous silicon layer 18 having a thickness of about 5 nm is then formed on the rear side of the substrate 10, and the n-type amorphous silicon layer 20 having a thickness of about 20 nm is further formed. Since each layer is sufficiently thin, the shape of each layer reflects the shapes of the textures 10a and 10b of the substrate 10. Specifically, the i-type amorphous silicon layer 12 and the p-type amorphous silicon layer 14 reflect the shape of the texture 10a of the substrate 10. The i-type amorphous silicon layer 18 and the n-type amorphous silicon layer 20 reflect the shape of the texture 10b of the substrate 10.

The transparent conductive layer 16 includes at least one of metal oxides such as indium oxide, zinc oxide, tin oxide, and titanium oxide. These metal oxides may be doped with a dopant such as tin, zinc, tungsten, antimony, titanium, cerium, or gallium. The conductive layer 22 may have the same configuration as the transparent conductive layer 16 or may have a different configuration. A metallic film made of a material having a high reflectance such as Ag, Cu, Al, Sn, or Ni or a metallic film made of an alloy of the above substances may be used as the conductive layer 22. The conductive layer 22 may have a stacked structure of a transparent conductive film and a metallic film. Thus, light which has entered from the light receiving surface is reflected by the metallic film, and power generation efficiency can be increased. The transparent conductive layer 16 and the conductive layer 22 can be formed by a film formation method such as a vapor deposition method, a CVD method, or the sputtering method. Since the transparent conductive layer 16 and the conductive layer 22 are also sufficiently thin, the transparent conductive layer 16 reflects the shape of the texture 10a of the substrate 10, and the conductive layer 22 reflects the shape of the texture 10b. Hereinafter, the textures formed on the surface of the photoelectric conversion unit 102 are also referred to as the textures 10a and 10b.

The collector electrodes 104 for taking out generated electric power are provided on the light receiving surface and the rear surface of the photoelectric conversion unit 102. The collector electrodes 104 include fingers 24. The fingers 24 are electrodes for collecting carriers generated in the photoelectric conversion unit 102. The fingers 24 are in the shape of lines having a width of, for example, about 100 μm to collect the carriers from the photoelectric conversion unit 102 as equally as possible, and are arranged at every 2 mm. The collector electrodes 104 may be further provided with bus bars 26 to connect the fingers 24. The bus bars 26 are collector electrodes for the carriers collected by the fingers 24. The bus bars 26 are in the shape of lines having a width of, for example, about 1 mm. The bus bars 26 are arranged across the fingers 24 along the direction in which connection members for connecting the solar cells 100 to form a solar cell module are arranged. The numbers and areas of the fingers 24 and the bus bars 26 are properly set in consideration of the area and resistance of the solar cell 100. The collector electrodes 104 may have a configuration which is not provided with the bus bars 26.

It is preferable that the placement area of the collector electrode 104 provided on the side of the light receiving surface of the solar cell 100 is smaller than the placement area of the collector electrode 104 provided on the rear side. That is, on the side of the light receiving surface of the solar cell 100, a light blocking loss can be reduced by minimizing the area for blocking incident light. On the other hand, the incident light does not need to be taken into consideration on the rear side, and the collector electrodes may be provided instead of the fingers 24 and the bus bars 26 over the entire rear surface of the solar cell 100.

The collector electrodes 104 can be formed by use of a conductive paste. The conductive paste can include an additive such as a conductive filler, a binder, or a solvent.

The conductive filler is mixed for the purpose of obtaining electric conductivity of the collector electrodes. Conductive particulate matter such as metallic particles of silver (Ag), copper (Cu), or nickel (Ni), carbon, and a mixture of the above is used as the conductive filler. Among the above, it is preferable to use the silver particles. The silver particles to be the conductive filler having different sizes or having depressed and projected shapes provided on the surface may be mixed.

It is preferable that the binder is a thermosetting resin. The binder in an uncured state is in a solid state that is soluble in a solvent or in a liquid or paste state (semisolid state) at room temperature. For example, a polyester resin, a phenol resin, a polyimide resin, a polycarbonate resin, a polysulfone resin, a melamine resin, an epoxy resin, or a mixture of the above resins is used as the binder. Among the above, the phenol resin, the melamine resin, and the epoxy resin are preferable, and the epoxy resin is particularly preferable. The conductive paste includes a hardening agent corresponding to the binder as required. The additive includes, for example, a rheology modifier, a plasticizer, a dispersant, and an antifoaming agent, in addition to the solvent.

The solvent includes, for example, ethers such as ethylene glycol monoethyl ether (ethylene Cellosolve), ethylene glycol monobutyl ether (butyl Cellosolve), ethylene glycol monophenyl ether, diethylene glycol monobutyl ether (butyl Carbitol), Cellosolve acetate, butyl Cellosolve acetate, Carbitol acetate, and butyl Carbitol acetate (hereinafter referred to as “BCA”); alcohols such as hexanol, octanol, decanol, stearyl alcohol, ceryl alcohol, cyclohexanol, and terpineol; ketones such as methyl ethyl ketone, methyl isobutyl ketone, and isophorone; esters such as ethyl acetate and butyl acetate; aromatic hydrocarbons solvent such as toluene and xylene; or a mixed solvent of the above.

The average particle size of the conductive filler contained in the conductive paste and a standard deviation σ of the particle size can be measured by a laser diffraction and scattering method. Diffracted and scattered light is generated from the conductive filler if laser is applied to the conductive filler, and the size of the conductive filler can be found in accordance with a spatial pattern of the intensity of the diffracted and scattered light in the direction of the light generation. According to the laser diffraction and scattering method, it is possible to find the size and the size distribution of the contained conductive filler by detecting and analyzing a light intensity distribution pattern in which the diffracted and scattered lights generated from a particle group of a large number of conductive fillers of different sizes contained in the conductive paste are superimposed.

The conductive paste is applied to the light receiving surface and rear surface of the photoelectric conversion unit 102 in a predetermined pattern, and heated and cured to form the collector electrodes 104. A heat treatment at a lower temperature may be conducted before the final heat and cure treatment.

The conductive paste can be applied to the light receiving surface and the rear surface in a predetermined pattern by a screen printing method. The screen printing method may be off-contact printing or on-contact printing.

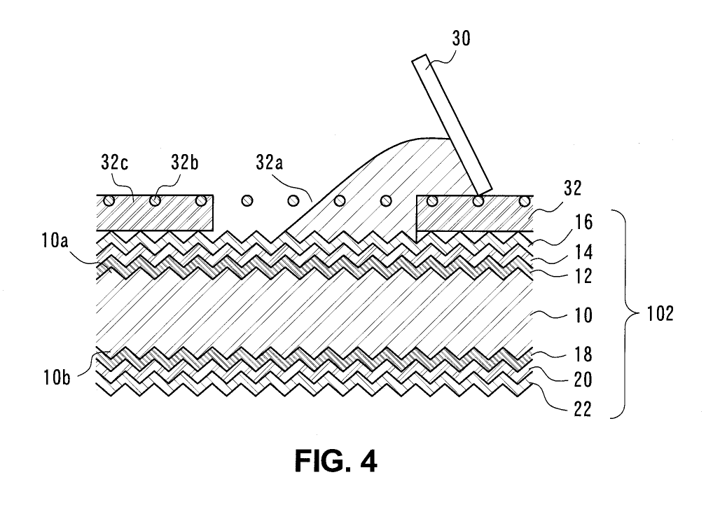

According to the screen printing method, as shown in FIG. 4, the conductive paste is transferred onto the photoelectric conversion unit 102 by use of a squeegee 30 made of a solvent-resistant elastic body and a screen plate 32 having an opening 32a corresponding to the shapes of the collector electrode 104. The screen plate 32 has a mesh 32b such as fabric which transmits the conductive paste, and a frame (not shown) in which the mesh 32b is stretched. The mesh 32b is provided with a mask material 32c corresponding to the region to which the conductive paste is not to be applied. Thus, a pattern of the opening 32a corresponding to the shape of the collector electrode 104 is formed in the screen plate 32.

The material, wire diameter, fineness of mesh, opening, and opening rate of the mesh 32b are selected by, for example, the width and thickness of an electrode to be formed. The material of the mesh 32b is, for example, a resin fiber of polyester or a metallic wire of stainless steel. The wire diameter of the mesh 32b is selected in accordance with, for example, the thickness of an electrode to be formed, and is preferably larger when the electrode is thicker. The fineness of mesh of the mesh 32b is selected in accordance with the strength of the mesh 32b and the fineness of an electrode to be formed. The opening of the mesh 32b is selected in accordance with the particle size of the conductive filler contained in the conductive paste, and is preferably twice the particle size or more in general. The opening rate of the mesh 32b is selected in accordance with the thickness and sagging width of an electrode to be formed. The material, wire diameter, number of meshes, opening, and opening rate of the mesh 32b are also selected by, for example, the material and application condition of the conductive paste.

In general, a photosensitive emulsion is used for the mask material 32c. The emulsion is selected in accordance with, for example, the material, resolution, and exposure sensitivity. For example, a diazo or stilbazolium material is used for the emulsion. A metallic foil can be used instead of the emulsion.

The squeegee 30 is made of a material suited to spreading the conductive paste over the screen plate 32. It is preferable that the squeegee 30 is made of a solvent-resistant elastic body. For example, urethane rubber is preferable.

Here, the relation between the size of the textures 10a and 10b on the surfaces of the photoelectric conversion unit 102 and the size of the conductive filler in the collector electrodes 104 is described.

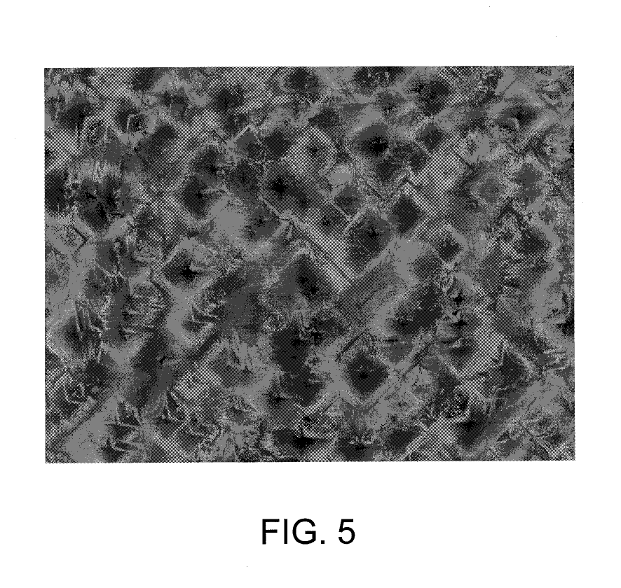

In general, as shown in FIG. 5, the vertices of the textures are irregularly arranged. Therefore, a linear path formed by the connection of valleys between a plurality of vertices is not straight but is bent. When the collector electrodes are formed by the screen printing, the conductive paste may flow to the outside of an electrode formation region through this path (hereinafter, the path is referred to as a “flow path”).

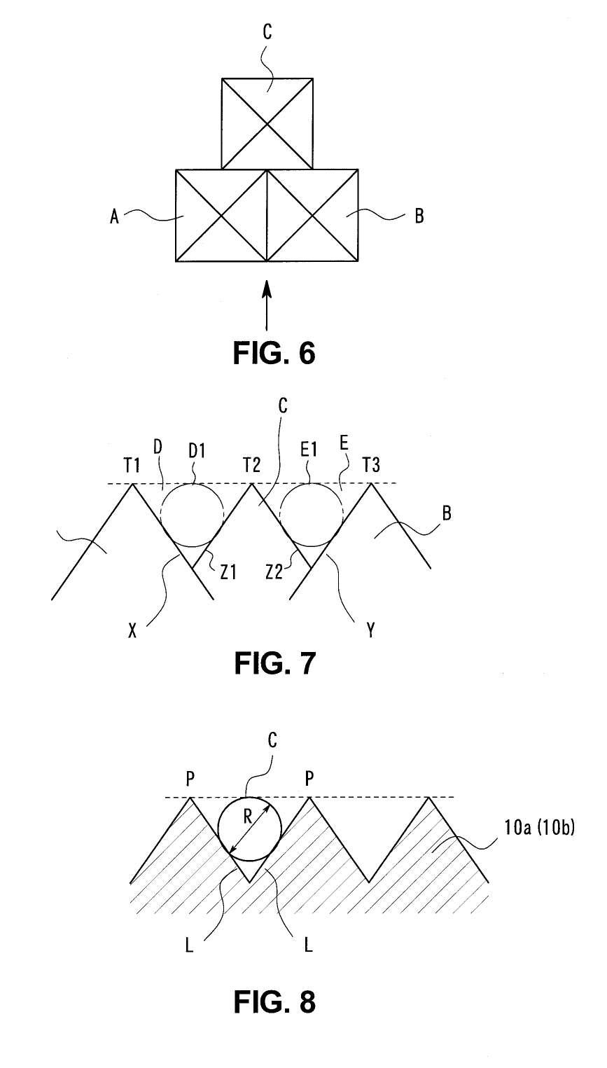

The relation between the size of the textures and the size of the conductive filler of the conductive paste in this case is described. FIG. 6 is a schematic view of the texture having the irregularly arranged vertices viewed from the upper side. FIG. 7 is a schematic view of FIG. 6 from the arrow (lateral) direction. Here, the “(lateral) direction” is a direction that intersects at right angles with the direction from the side of the light receiving surface to the rear surface. In FIGS. 6 and 7, for ease of explanation, textures A to C are the same size, and the vertex of the texture C on the far side is configured to be located midway between the textures A and B on the near side.

As shown in FIG. 6, if the vertices are irregularly arranged, other textures are arranged to block the flow path in the direction in which the valley between the vertices extends. In a conventional configuration, the average particle size of the conductive filler is smaller than the diameters of inscribed circles D1 and E1 formed in spaces D and E surrounded by ridgelines X and Y of the textures A and B on the near side, ridgelines Z1 and Z2 of the texture C on the far side, and a virtual line that connects vertices T1 to T3 of the textures A to C, in the schematic view shown in FIG. 7. In such a configuration, the conductive paste easily flows out of the electrode formation region through the spaces D and E during the formation of the collector electrode 104. That is, even if the flow path is blocked by the textures, the conductive paste flows out from the gap between the blocking textures. The vertices of the textures A to C are points that protrude the most on the light receiving surface in the direction from the rear surface to the light receiving surface.

Thus, in the present embodiment, the average size of the textures 10a and 10b is formed so that the diameters of the inscribed circles D1 and E1 formed in the spaces D and E are smaller than the average particle size of the conductive filler. Consequently, when the flow path is blocked by the textures, the outflow of the conductive paste from the gap between the blocking textures can be inhibited. Since the flow path is narrower, the moving distance of the conductive paste in the flow path is inhibited by a pressure loss. Therefore, the seepage of the conductive paste outside the electrode formation region can be inhibited, and a light blocking loss caused to the solar cell 100 can be reduced.

Table 1 shows the differences of the line width, electrode width, and bleeding (one side) of the collector electrode 104 in the Example of the configuration according to the present embodiment described above and in the Comparative Example of the conventional configuration. The electrode width of the collector electrode 104 means the width of the region having a thickness which sufficiently functions as the collector electrode 104 along the direction that intersects at right angles with the longitudinal direction of the collector electrode 104. The bleeding of the collector electrode 104 means the width of the region running over the electrode width of the collector electrode 104 along the direction that intersects at right angles with the longitudinal direction of the collector electrode 104 because of the depressions and projections of the textures. The bleeding of the collector electrode 104 occurs on both sides of the width direction of the collector electrode 104, but indicates the average value of the width of bleeding on one side in Table 1. The line width of the collector electrode 104 means a width in which the electrode width of the collector electrode 104 and the bleeding are added together, and is represented here by line width=electrode width+bleeding×2.

TABLE 1

| | | Line | Electrode | Bleeding |
|---|---|---|---|---|
| | | width | width | (one side) |
| Comparative | Average | 96.9 | 66.9 | 15.0 |
| Example | (μm) | | | |
| | Standard | 1.6 | 4.7 | 1.7 |
| | deviation | | | |
| | σ | | | |
| Example | Average | 92.8 | 67.0 | 12.9 |
| | (μm) | | | |
| | Standard | 1.8 | 2.3 | 0.8 |
| | deviation | | | |
| | σ | | | |

In the Example, the average value of the electrode width of the collector electrode 104 was substantially equal, but its standard deviation was lower, and the collector electrode 104 could be formed with a high degree of accuracy and reliability, in contrast with the Comparative Example. Moreover, in the Example, the average value of the bleeding of the collector electrode 104 and the standard deviation σ were lower, showing that the seepage of the conductive paste during the formation of the collector electrode 104 could be inhibited, in contrast with the Comparative Example. Thus, a light blocking loss caused in the solar cell 100 could be reduced.

As shown in FIG. 8, it is preferable that the average size of the textures 10a and 10b on the surfaces of the photoelectric conversion unit 102 is formed so that an average diameter R of an inscribed circle C of a triangle formed by ridgelines L of the textures 10a and 10b and a line that connects the adjacent vertices P of the textures 10a and 10b is less than or equal to the average particle size of the conductive filler of the collector electrode 104.

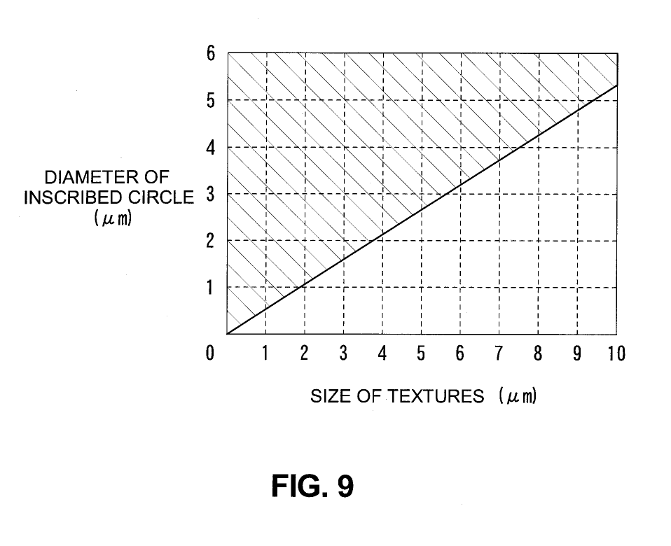

FIG. 9 is a graph showing the relation between the average size of the textures and the diameter R of the inscribed circle C shown in FIG. 8. That is, it is preferable that the average particle size of the conductive filler of the collector electrode 104 is within the upper range across the straight line in FIG. 9.

If the average particle size of the conductive filler of the collector electrode 104 satisfies the above conditions, the seepage of the conductive paste can be further inhibited, and a light blocking loss caused in the solar cell 100 can be further reduced.

The applicable scope of the present invention is not limited to the solar cell according to the present embodiment, and a solar cell has only to have a texture on the light receiving surface or on the rear surface. For example, the present invention is applicable to a solar cell of a crystalline type or a thin film type.

1. A solar cell comprising:
a photoelectric conversion unit which has a first surface and a second surface opposite to the first surface and in which textures are formed on at least the first surface; and
an electrode which is formed on the first surface and which includes a plurality of conductive particles,
wherein the average size of the textures is formed so that the diameter of an inscribed circle in a space surrounded by the ridgelines of a plurality of textures that are adjacent to each other among the above textures and a virtual line that connects the vertices of the adjacent textures is smaller than the average particle size of the conductive particles.

2. The solar cell according to claim 1, wherein
when the textures are laterally viewed, first and second adjacent textures are arranged on the near side, a third texture is adjacently arranged on the far side so that the vertex thereof is located midway between the first texture and the second texture, and the first to third textures have the average size, in which case the space is surrounded by the ridgelines of the first to third textures and a virtual line that connects the vertices of the first to third textures.

3. The solar cell according to claim 1, wherein
when the textures are laterally viewed, first and second adjacent textures are arranged, and the first and second textures have the average size, in which case the space is surrounded by the ridgelines of the first and second textures and a virtual line that connects the vertices of the first and second textures.

4. The solar cell according to claim 1, wherein
the photoelectric conversion unit comprises
a crystalline semiconductor substrate on which the textures are provided, and
an amorphous semiconductor layer formed on the crystalline semiconductor substrate.

5. The solar cell according to claim 4, wherein
the photoelectric conversion unit further comprises
a transparent conductive layer formed on the amorphous semiconductor layer on the side of a light receiving surface.
